(19) United States
(12) Patent Application Publication
(10) Pub. No.: US 2016/0036392 A1
(43) Pub. Date: Feb. 4, 2016

(54) DUAL-BAND AMPLIFIER

(71) Applicant: QUALCOMM Incorporated, San Diego, CA (US)

(72) Inventors: Mounir Bohsali, Alamo, CA (US); Anup Savla, Santa Clara, CA (US)

(21) Appl. No.: 14/447,395

(22) Filed: Jul. 30, 2014

(51) Int. Cl. H03F 1/26; H03F 1/56; H04L 27/26

(52) U.S. Cl. CPC H03F 1/26; H04L 27/2649; H03F 1/565; H03F 2200/372; H03F 2200/294

(57) ABSTRACT

An apparatus includes: a first amplifier stage configured to receive an input signal through a first gate inductor and a first source inductor; and a second amplifier stage configured to receive the input signal through the first gate inductor in series with a second gate inductor and the first source inductor in series with a second source inductor.

### BACKGROUND

I. Field

The present disclosure relates generally to electronics, and more specifically to dual-band amplifiers.

II. Background

A wireless device (e.g., a cellular phone or a smartphone) in a wireless communication system may transmit and receive data for two-way communication. The wireless device may include a transmitter for data transmission and a receiver for data reception. For data transmission, the transmitter may modulate a radio frequency (RF) carrier signal with data to obtain a modulated RF signal, amplify the modulated RF signal to obtain an amplified RF signal having the proper output power level, and transmit the amplified RF signal via an antenna to a base station. For data reception, the receiver may obtain a received RF signal via the antenna and may amplify and process the received RF signal to recover data sent by the base station. The receiver may include a low noise amplifier (LNA) coupled to an antenna using various front-end circuit blocks that perform functions including impedance matching. Each of these circuit blocks may have insertion loss, which may degrade the noise figure (NF) of the receiver and hence degrade the performance of the receiver. Difficulties exist in impedance matching especially when designing, for example, a dual-band wireless local area network LNA that can operate at two different frequencies (e.g., at 2.4 GHz and 5 GHz).

### BRIEF DESCRIPTION OF THE DRAWINGS

FIG. 1 is a wireless device communicating with a wireless communication system.

FIG. 2 is a block diagram of an exemplary design of wireless device shown in FIG. 1.

FIG. 3 is a schematic diagram of an exemplary dual-band LNA which includes a gain transistor in a common-source configuration and a cascode transistor in a common-gate configuration.

FIG. 4A shows a plot of various parameters of the LNA shown in FIG. 3 at the second frequency (i.e., at 2.4 GHz).

FIG. 4B shows a plot of various parameters of the LNA shown in FIG. 3 at the first frequency (i.e., at 5.0 GHz).

FIG. 5A is a block diagram of an exemplary dual-band LNA which includes two amplifier stages in accordance with one exemplary embodiment of the present disclosure.

FIG. 5B is a schematic diagram of an exemplary dual-band LNA which includes two amplifier stages in accordance with one exemplary embodiment of the present disclosure.

FIG. 5C is a schematic diagram of another exemplary dual-band LNA which includes two amplifier stages in accordance with one exemplary embodiment of the present disclosure.

FIG. 6A shows a plot of various parameters of the LNA shown in FIG. 5B at the second frequency (i.e., at 2.4 GHz).

FIG. 6B shows a plot of various parameters of the LNA shown in FIG. 5B at the first frequency (i.e., at 5.0 GHz).

FIG. 7 is an exemplary flow diagram of a process for operating a dual-band LNA in stages according to one exemplary embodiment of the present disclosure.

### DETAILED DESCRIPTION

The detailed description set forth below is intended as a description of exemplary designs of the present disclosure and is not intended to represent the only designs in which the present disclosure can be practiced. The term “exemplary” is used herein to mean “serving as an example, instance, or illustration.” Any design described herein as “exemplary” is not necessarily to be construed as preferred or advantageous over other designs. The detailed description includes specific details for the purpose of providing a thorough understanding of the exemplary designs of the present disclosure. It will be apparent to those skilled in the art that the exemplary designs described herein may be practiced without these specific details. In some instances, well-known structures and devices are shown in block diagram form in order to avoid obscuring the novelty of the exemplary designs presented herein.

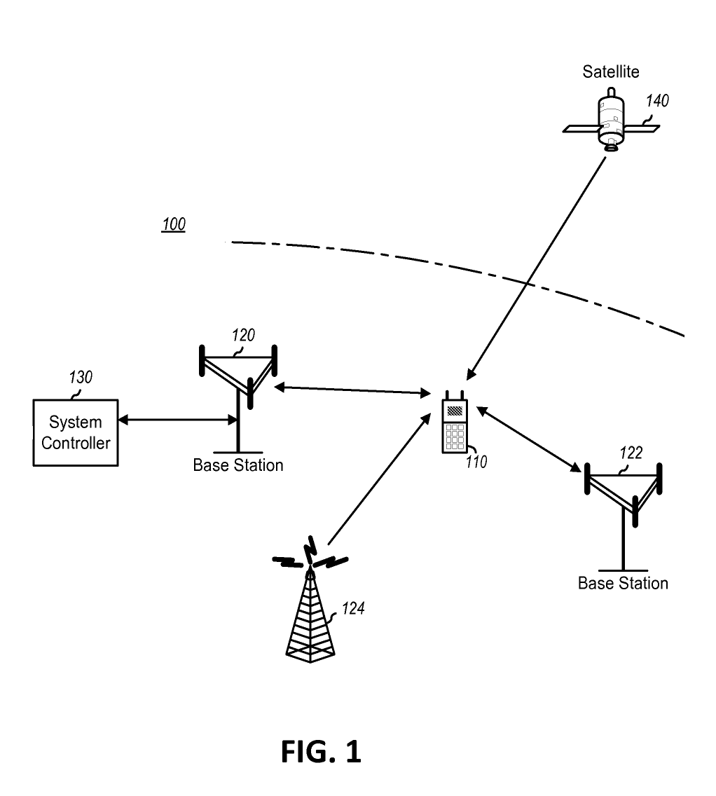

FIG. 1 is a wireless device 110 communicating with a wireless communication system 100. Wireless system 100 may be a Long Term Evolution (LTE) system, a Code Division Multiple Access (CDMA) system, a Global System for Mobile Communications (GSM) system, a wireless local area network (WLAN) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 1 shows wireless system 100 including two base stations 120 and 122 and one system controller 130. In general, a wireless system may include any number of base stations and any set of network entities.

Wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a cordless phone, a wireless local loop (WLL) station, a Bluetooth device, etc. Wireless device 110 may communicate with wireless system 100. Wireless device 110 may also receive signals from broadcast stations (e.g., a broadcast station 124), signals from satellites (e.g., a satellite 140) in one or more global navigation satellite systems (GNSS), etc. Wireless device 110 may support one or more radio technologies for wireless communication such as LTE, WCDMA, CDMA 1X, EVDO, TD-SCDMA, GSM, 802.11, etc.

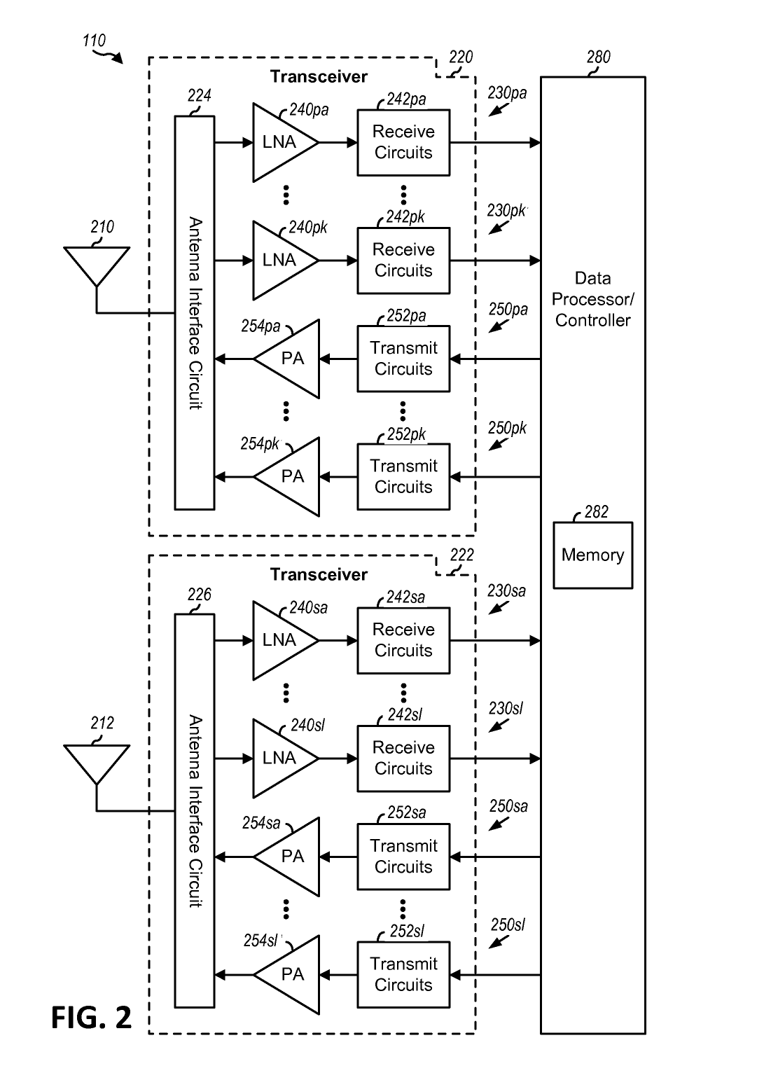

FIG. 2 is a block diagram of an exemplary design of wireless device 110 shown in FIG. 1. In this exemplary design, wireless device 110 includes a transceiver 220 coupled to a primary antenna 210, a transceiver 222 coupled to a secondary antenna 212, and a data processor/controller 280. Transceiver 220 includes multiple (k) receivers 230pa to 230pk and multiple (k) transmitters 250pa to 250pk to support multiple frequency bands, multiple radio technologies, carrier aggregation, etc. Transceiver 222 includes multiple (l) receivers 230sa to 230sl and multiple (l) transmitters 250sa to 250sl to support multiple frequency bands, multiple radio technologies, carrier aggregation, receive diversity, multiple-input multiple-output (MIMO) transmission from multiple transmit antennas to multiple receive antennas, etc.

In the exemplary design shown in FIG. 2, each receiver 230 includes an LNA 240 and receive circuits 242. For data reception, antenna 210 receives signals from base stations and/or other transmitter stations and provides a received RF signal, which is routed through an antenna interface circuit 224 and presented as an input RF signal to a selected receiver. Antenna interface circuit 224 may include switches, duplexers, transmit filters, receive filters, matching circuits, etc. The description below assumes that receiver 230pa is the selected receiver. Within receiver 230pa, an LNA 240pa amplifies the input RF signal and provides an output RF signal. Receive circuits 242pa downconvert the output RF signal from RF to baseband, amplify and filter the downconverted signal, and provide an analog input signal to data processor 280. Receive circuits 242pa may include mixers, filters, amplifiers, matching circuits, an oscillator, a local oscillator (LO) generator, a phase locked loop (PLL), etc. Each remaining receiver 230 in transceivers 220 and 222 may operate in similar manner as receiver 230pa.

In the exemplary design shown in FIG. 2, each transmitter 250 includes transmit circuits 252 and a power amplifier (PA) 254. For data transmission, data processor 280 processes (e.g., encodes and modulates) data to be transmitted and provides an analog output signal to a selected transmitter. The description below assumes that transmitter 250pa is the selected transmitter. Within transmitter 250pa, transmit circuits 252pa amplify, filter, and upconvert the analog output signal from baseband to RF and provide a modulated RF signal. Transmit circuits 252pa may include amplifiers, filters, mixers, matching circuits, an oscillator, an LO generator, a PLL, etc. A PA 254pa receives and amplifies the modulated RF signal and provides a transmit RF signal having the proper output power level. The transmit RF signal is routed through antenna interface circuit 224 and transmitted via antenna 210. Each remaining transmitter 250 in transceivers 220 and 222 may operate in similar manner as transmitter 250pa.

FIG. 2 also shows an exemplary design of receiver 230 and transmitter 250. A receiver and a transmitter may also include other circuits not shown in FIG. 2, such as filters, matching circuits, etc. All or a portion of transceivers 220 and 222 may be implemented on one or more analog integrated circuits (ICs), RF ICs (RFICs), mixed-signal ICs, etc. For example, LNAs 240 and receive circuits 242 within transceivers 220 and 222 may be implemented on multiple IC chips. The circuits in transceivers 220 and 222 may also be implemented in other manners.

Data processor/controller 280 may perform various functions for wireless device 110. For example, data processor 280 may perform processing for data being received via receivers 230 and data being transmitted via transmitters 250. Controller 280 may control the operation of the various circuits within transceivers 220 and 222. A memory 282 may store program codes and data for data processor/controller 280. Data processor/controller 280 may be implemented on one or more application specific integrated circuits (ASICs) and/or other ICs.

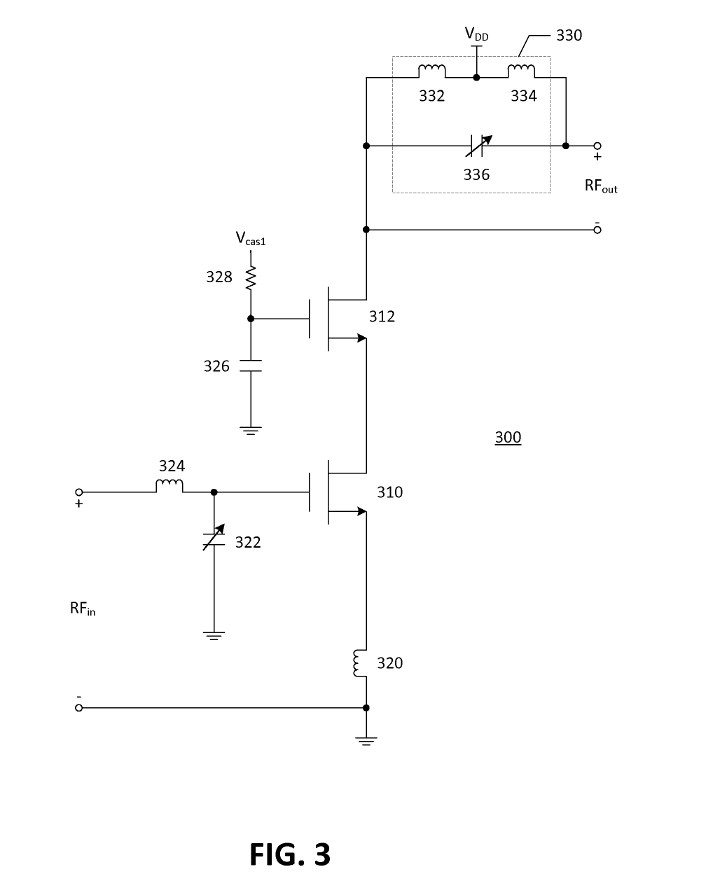

FIG. 3 is a schematic diagram of an exemplary dual-band LNA 300 which includes a gain transistor 310 in a common-source configuration and a cascode transistor 312 in a common-gate configuration. The LNA 300 may be used for any one of LNAs 240 in FIG. 2. In FIG. 3, RFᵢₙ defines a single-ended radio frequency (RF) input terminal and RFₒᵤₜ defines a differential RF output terminal.

Input impedance matching is performed using two inductors 324 (gate inductor), 320 (source degeneration inductor) and a variable capacitor 322. Output impedance matching is performed using an output LC load 330 including two inductors 332, 334 and a variable capacitor 336. In this exemplary embodiment, the impedance matching is performed by varying the capacitance of a capacitor. For example, in the design of FIG. 3, to perform input impedance matching at a first frequency (e.g., at a relatively high frequency of 5.0 GHz), capacitor 322 is set to zero. For input matching at a second frequency (e.g., at a relatively low frequency of 2.4 GHz), 322 is increased above zero. In one exemplary embodiment, variable capacitor 322 may be present across the gate and source terminals of the gain transistor 310. Capacitor 322 may include parasitic capacitance of gain transistor 310. Capacitor 322 may also include a bank of switchable capacitors, which may be coupled between the gate and source of the gain transistor 310 and may be used to fine-tune the input impedance of the LNA 300. Each switchable capacitor may be implemented with a capacitor coupled in series with a switch. The capacitors in the bank may be selected to obtain good input matching for the LNA 300. However, when operating at the second frequency, this increase in capacitance at the gate of the common-source gain transistor 310 decreases the gain and increases the noise figure (NF) of the LNA 300.

In the exemplary LNA 300 shown in FIG. 3, a gain transistor 310 has its gate terminal receiving an input RF signal at the RF input terminal and its source terminal coupled to one end of the source degeneration inductor 320. The other end of the source degeneration inductor 320 couples to the ground voltage. A cascode transistor 312 has its source terminal coupled to the drain terminal of the gain transistor 310, its gate terminal receiving a cascode control signal (V_{cas1}), and its drain terminal coupled to one of the differential RF output terminal (RFₒᵤₜ⁻). The gain transistor 310 and the cascode transistor 312 may be implemented with N-channel metal oxide semiconductor (PMOS) transistors, as shown in FIG. 3, or with transistors of other types.

The exemplary LNA 300 is coupled to a load circuit 330, which includes two inductors 332, 334 and a variable capacitor 336. The first end of the variable capacitor 336 is coupled to the drain terminal of the cascode transistor 312 and to the first terminal of the differential RF output terminal (RFₒᵤₜ⁻). The second end of the variable capacitor 336 is coupled to the second terminal of the differential RF output terminal (RFₒᵤₜ⁺). The first end of the inductor 332 is coupled to the drain terminal of the cascode transistor 312, while the second end of the inductor 322 is coupled to the supply voltage (V_{DD}) and the first end of the inductor 334. The second end of the inductor 334 is coupled to the second terminal of the differential RF output terminal (RFₒᵤₜ⁺). In one exemplary embodiment, the differential RF output terminal is provided to a downconverter to downconvert the output RF signal from RF to baseband.

The output LC load 330 may also be implemented in other manners. In one exemplary design, the output LC load 330 may include a transformer comprising a primary coil and a secondary coil. The primary coil can be coupled between the output of the LNA 300 and the supply voltage (V_{DD}) and the secondary coil can provide the differential RF output signal to the downconverter. In another exemplary design, the output LC load 330 may include a P-channel metal oxide semiconductor (PMOS) transistor having its source terminal coupled to the supply voltage (V_{DD}) and its drain terminal coupled to the drain terminal of a cascode transistor 312. The PMOS transistor may provide an active load for cascode transistor 312.

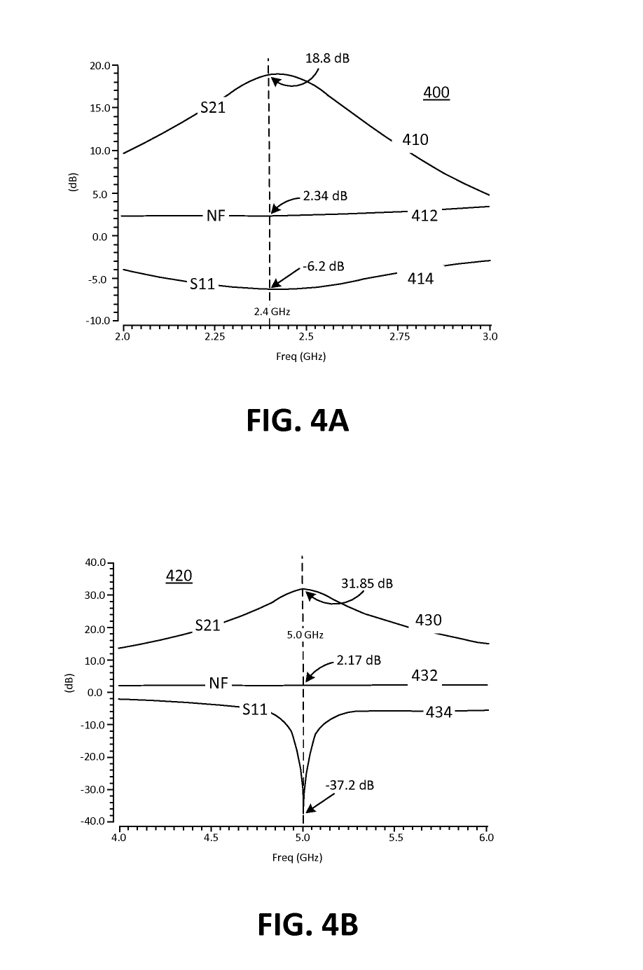

FIG. 4A shows plot 400 of various parameters of the LNA 300 shown in FIG. 3 at the second frequency (i.e., at 2.4 GHz). The plot 400 includes graphs for input matching (S11) 414, gain (S21) 410, and the noise figure (NF) 412 produced by the dual-band LNA 300. Although the exact numbers may vary depending on the setup of the test, the design of the LNA 300 as configured in FIG. 3 provides a gain 410 of 18.8 dB, an NF 412 of 2.34 dB, and an input matching 414 of −6.2 dB.

FIG. 4B shows plot 420 of various parameters of the LNA 300 shown in FIG. 3 at the first frequency (i.e., at 5.0 GHz). The plot 420 includes graphs for input matching (S11) 434, gain (S21) 430, and the noise figure (NF) 432 produced by the dual-band LNA 300. Although the exact numbers may vary depending on the setup of the test, the design of the LNA 300 as configured in FIG. 3 provides a gain 430 of 31.85 dB, an NF 432 of 2.17 dB, and an input matching 434 of −37.2 dB.

As can be seen from the above plots 400, 420, the increased gate capacitance (e.g., at the gate terminal of the common-source gain transistor 310) at the second frequency (i.e., at 2.4 GHz) decreases the gain 410, 430 (from 31.8 dB at 5.0 GHz to 18.8 dB at 2.4 GHz) and increases the NF 412, 432 (from 2.17 dB to 2.34 dB). To address the problem of a decrease in the gain and increase in the NF of the LNA 300 due to the increased gate capacitance when operating at the second frequency (e.g., at a low frequency of 2.4 GHz), a second branch including a gain transistor and a cascode transistor can be added. The second branch is configured to turn on only when the LNA is operating at the second frequency. Thus, with the added second branch, the input impedance matching is performed using inductors rather than a variable capacitor.

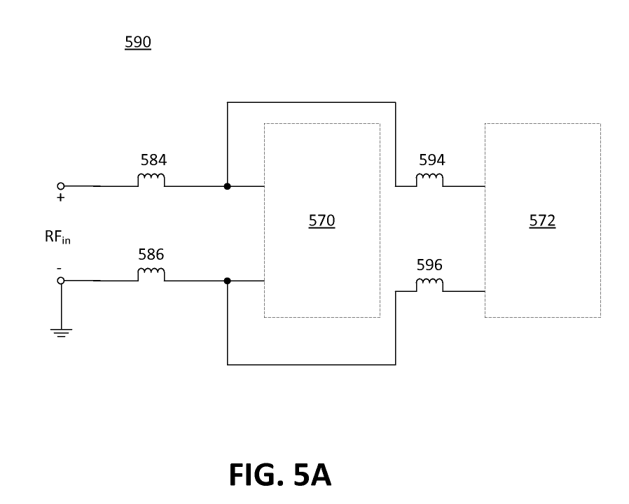

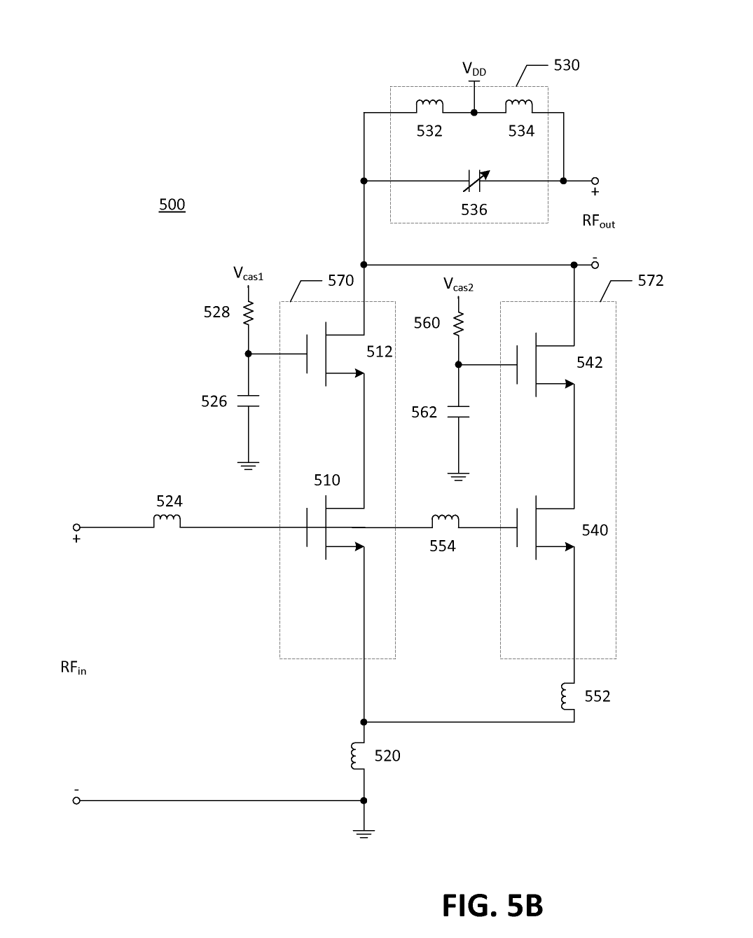

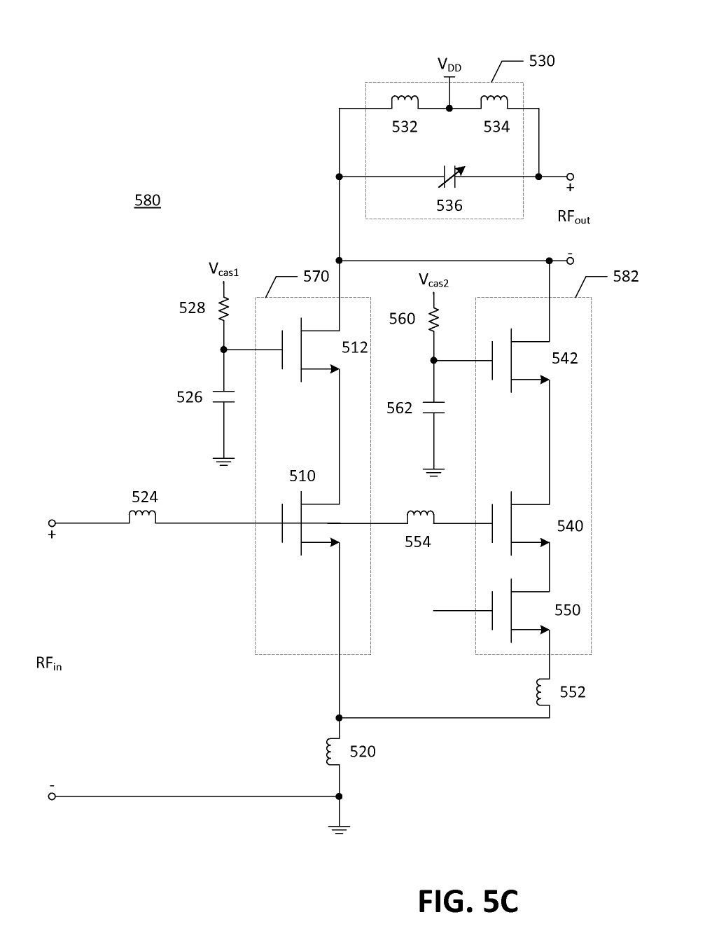

FIG. 5A is a block diagram of an exemplary dual-band LNA 590 which includes two amplifier stages 570, 572 in accordance with one exemplary embodiment of the present disclosure. The LNA 590 may be used for any one of LNAs 240 in FIG. 2. In the exemplary LNA 590 shown in FIG. 5A, the input impedance matching is performed by varying the inductors 584, 594 and 586, 596.

The exemplary dual-band LNA 590 shown in FIG. 5A receives an input RF signal (RFᵢₙ), which is applied to both first and second amplifier stages 570, 572. When the dual-band LNA 590 is operating at a first frequency (i.e., a high frequency mode; e.g., at 5.0 GHz), only the first amplifier stage 570 is operated. The first amplifier stage 570 is configured to receive the input RF signal through a first gate inductor 584 and a first source inductor 586. When the dual-band LNA 590 is operating at a second frequency (i.e., a low frequency mode; e.g., at 2.4 GHz), only the second amplifier stage 572 is operated. The second amplifier stage 572 is configured to receive the input RF signal through the first gate inductor 584 and a second gate inductor 594 configured in a series, and the first source inductor 586 and a second source inductor 596 configured in a series.

FIG. 5B is a schematic diagram of an exemplary dual-band LNA 500 which includes two amplifier stages 570, 572 in accordance with one exemplary embodiment of the present disclosure. The first amplifier stage 570 includes a gain transistor 510 in a common-source configuration and a cascode transistor 512 in a common-gate configuration. The second amplifier stage 572 includes a gain transistor 540 in a common-source configuration and a cascode transistor 542 in a common-gate configuration. The LNA 500 may be used for any one of LNAs 240 in FIG. 2. Further, in the exemplary LNA 500 shown in FIG. 5B, the variable capacitor (322 in FIG. 3) at the gate of the common-source transistor is removed and the input impedance matching is performed by varying the inductors 524, 554 and 552, 520.

In the exemplary LNA 500 shown in FIG. 5B, each amplifier stage 570, 572 includes a gain transistor 510, 540 which has its gate terminal receiving an input RF signal at the RF input terminal. The source terminal of the gain transistor 510 in the first amplifier stage 570 couples to one end of the source degeneration inductor 520. The other end of the source degeneration inductor 520 couples to the ground voltage. The cascode transistor 512 in the first amplifier stage 570 has its source terminal coupled to the drain terminal of the gain transistor 510, its gate terminal receiving a first cascode control signal (V_{cas1}), and its drain terminal coupled to one of the differential RF output terminal (RFₒᵤₜ⁻). Further, the source terminal of the gain transistor 540 in the second amplifier stage 572 couples to one end of the inductor 552. The other end of the inductor 552 couples to the inductor 520. The cascode transistor 542 in the second amplifier stage 572 has its source terminal coupled to the drain terminal of the gain transistor 540, its gate terminal receiving a second cascode control signal (V_{cas2}), and its drain terminal coupled to one of the differential RF output terminal (RFₒᵤₜ⁻). The gain transistors 510, 540 and the cascode transistor 512, 542 may be implemented with N-channel metal oxide semiconductor (NMOS) transistors, as shown in FIG. 5B, or with transistors of other types.

The exemplary dual-band LNA 500 shown in FIG. 5B receives an input RF signal (RFᵢₙ), which is applied to both first and second amplifier stages 570, 572. When the dual-band LNA 500 is operating at a first frequency (i.e., a high frequency mode; e.g., at 5.0 GHz), only the first amplifier stage 570 is operated. The cascode control signal (V_{cas1}) of the first amplifier stage 570 is set to a voltage that is high enough to turn on the cascode transistor 512 which applies current through resistor 528 and charges up capacitor 526. At this operating mode, the second amplifier stage 572 (including transistors 540, 542) is turned off by setting the cascode control signal (V_{cas2}) of the second amplifier stage 572 to the ground voltage.

When the dual-band LNA 500 is operating at the second frequency (i.e., a low frequency mode; e.g., at 2.4 GHz), only the second amplifier stage 572 is operated. The cascode control signal (V_{cas2}) of the second amplifier stage 572 is set to a voltage that is high enough to turn on the cascode transistor 542 which applies current through resistor 560 and charges up capacitor 562. At this operating mode, the first amplifier stage 570 (including transistors 510, 512) is turned off by setting the cascode control signal (V_{cas1}) of the first amplifier stage 570 to the ground voltage. Thus, in this low frequency mode, transistor 540 is the common-source transistor. The gate inductor includes two inductors 524 and 554 in series and the source inductor includes two inductors 552 and 520 in series. Thus, when operating at the second frequency, gate inductor 554 is added to the existing gate inductor 524 and source inductor 552 is added to the existing source inductor 520. Accordingly, the dual-band LNA 500 can be configured for the operation at the second frequency (e.g., 2.4 GHz) by selecting appropriate values for gate inductors 524 and 554 and source inductors 552 and 520 that will provide good input impedance matching at the second frequency.

The exemplary LNA 500 is coupled to a load circuit 530, which includes two inductors 532, 534 and a variable capacitor 536. The first end of the variable capacitor 536 is coupled to the drain terminals of the cascode transistors 512, 542 and to the first terminal of the differential RF output terminal (RFₒᵤₜ⁻). The second end of the variable capacitor 536 is coupled to the second terminal of the differential RF output terminal (RFₒᵤₜ⁺). The first end of the inductor 532 is coupled to the drain terminals of the cascode transistors 512, 542, while the second end of the inductor 532 is coupled to the supply voltage (V_{DD}) and the first end of the inductor 534. The second end of the inductor 534 is coupled to the second terminal of the differential RF output terminal (RFₒᵤₜ⁺). In one exemplary embodiment, the differential RF output terminal is provided to a downconverter to downconvert the output RF signal from RF to baseband.

The output LC load 530 may also be implemented in other manners. In one exemplary design, the output LC load 530 may include a transformer comprising a primary coil and a secondary coil. The primary coil can be coupled between the output of the LNA 500 and the supply voltage (V_{DD}) and the secondary coil can provide the differential RF output signal to the downconverter. In another exemplary design, the output LC load 530 may include a P-channel metal oxide semiconductor (PMOS) transistor having its source terminal coupled to the supply voltage (V_{DD}) and its drain terminal coupled to the drain terminals of the cascode transistors 512, 542. The PMOS transistor may provide an active load for cascode transistors 512, 542.

FIG. 5C is a schematic diagram of another exemplary dual-band LNA 580 which includes two amplifier stages 570, 582 in accordance with another embodiment of the present disclosure. In the exemplary LNA 580 shown in FIG. 5C, each amplifier stage 570, 582 includes a gain transistor 510, 540 which has its gate terminal receiving an input RF signal at the RF input terminal. The source terminal of the gain transistor 510 in the first amplifier stage 570 couples to one end of the source degeneration inductor 520. The other end of the source degeneration inductor 520 couples to the ground voltage. The cascode transistor 512 in the first amplifier stage 570 has its source terminal coupled to the drain terminal of the gain transistor 510, its gate terminal receiving a first cascode control signal (V_{cas1}), and its drain terminal coupled to one of the differential RF output terminal (RFₒᵤₜ⁻). Further, the source terminal of the second amplifier stage 582 couples to the drain terminal of another MOS transistor 550 which acts as a source switch to completely turn off the second amplifier stage 572 when it is not in use. The source terminal of the transistor 550 in the second amplifier stage 582 couples to one end of the inductor 552. The other end of the inductor 552 couples to the inductor 520. The cascode transistor 542 has its source terminal coupled to the drain terminal of the gain transistor 540, its gate terminal receiving a second cascode control signal (V_{cas2}), and its drain terminal coupled to one of the differential RF output terminal (RFₒᵤₜ⁻).

Although setting V_{cas2} to the ground voltage turns off the cascode transistor 542 and no current is supplied to transistors 540, 550 and inductor 552, parasitic capacitance from the transistors in the second amplifier stage 582 can cause the capacitance from the second amplifier stage 582 to leak into the first amplifier stage 570. Thus, when the LNA 580 is operating at the high frequency mode with only the first amplifier stage 570, the second amplifier stage 582 is completely turned off by setting V_{cas2} to the ground voltage and also by turning off the source switch transistor 550 (for example, by setting the gate terminal of transistor 550 to the ground voltage). This prevents the parasitic capacitance of the second amplifier stage 582 from leaking into the first amplifier stage 570 and interfering with the operation of the first amplifier stage 570.

When the dual-band LNA 580 is operating at the second frequency (i.e., a low frequency mode; e.g., at 2.4 GHz), only the second amplifier stage 582 is operated. The cascode control signal (V_{cas2}) of the second amplifier stage 582 is set to a voltage that is high enough to turn on the cascode transistor 542 which applies current through resistor 560 and charges up capacitor 562. At this operating mode, the first amplifier stage 570 (including transistors 510, 512) is turned off by setting the cascode control signal (V_{cas1}) of the first amplifier stage 570 to the ground voltage. Thus, in this low frequency mode, transistor 540 is the common-source transistor. The gate inductor includes two inductors 524 and 554 in series and the source inductor includes two inductors 552 and 520 in series. Thus, when operating at the second frequency, gate inductor 554 is added to the existing gate inductor 524 and source inductor 552 is added to the existing source inductor 520. Accordingly, the dual-band LNA 580 can be configured for the operation at the second frequency (e.g., 2.4 GHz) by selecting appropriate values for gate inductors 524 and 554 and source inductors 552 and 520 that will provide good input impedance matching at the second frequency. In this mode, the source switch transistor 550 is turned on (for example, by setting the gate of transistor 550 to a bias voltage higher than the threshold voltage).

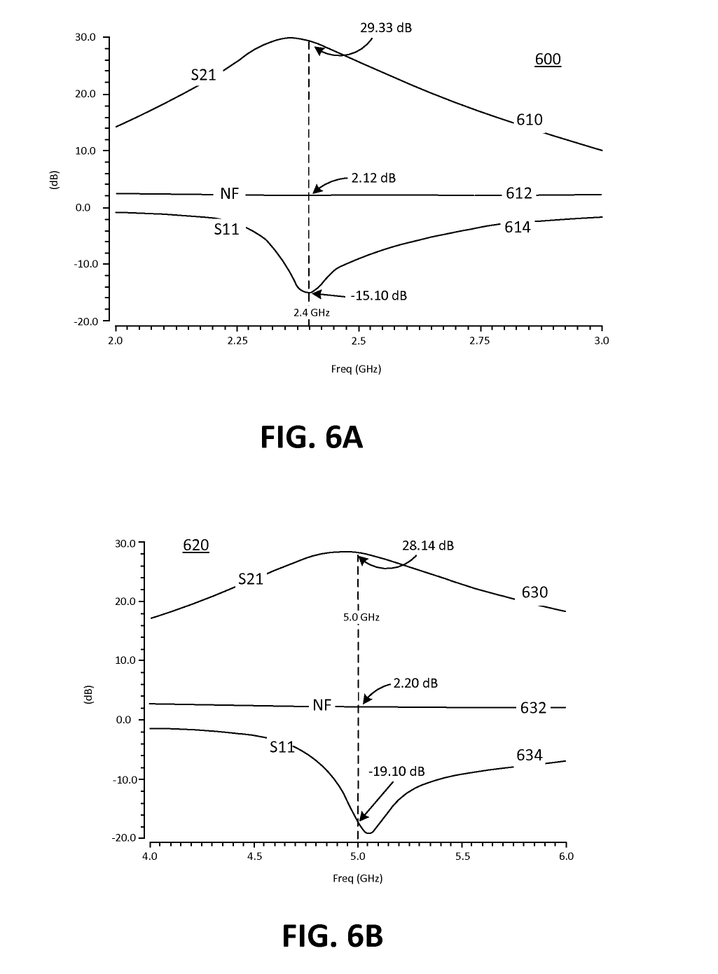

FIG. 6A shows plot 600 of various parameters of the LNA 500 shown in FIG. 5B at the second frequency (i.e., at 2.4 GHz). The plot 600 includes graphs for input matching (S11) 614, gain (S21) 610, and the noise figure (NF) 612 produced by the dual-band LNA 500. Although the exact numbers may vary depending on the setup of the test, the design of the LNA 500 as configured in FIG. 5B provides a gain 610 of 29.33 dB, an NF 612 of 2.12 dB, and an input matching 614 of −15.10 dB.

FIG. 6B shows plot 620 of various parameters of the LNA 500 shown in FIG. 5B at the first frequency (i.e., at 5.0 GHz). The plot 620 includes graphs for input matching (S11) 634, gain (S21) 630, and the noise figure (NF) 632 produced by the dual-band LNA 500. Although the exact numbers may vary depending on the setup of the test, the design of the LNA 500 as configured in FIG. 5B provides a gain 630 of 28.14 dB, an NF 632 of 2.20 dB, and an input matching 634 of −19.10 dB.

As can be seen from the above plot 600 of FIG. 6A, at the second frequency (e.g., at 2.4 GHz), the dual-band LNA 500 provides good input impedance matching (S11) and substantial increase in the gain (S21) over the dual-band LNA 300. For example, the gain (S21) has increased from 18.8 dB for the dual-band LNA 300 to 29.3 dB for the dual-band LNA 500, which is an increase of almost 56%. In another example, the impedance matching (S11) has significantly improved from −6.2 dB for the dual-band LNA 300 to −15.10 dB for the dual-band LNA 500. In yet another example, the NF has slightly improved from 2.34 dB for dual-band LNA 300 to 2.12 dB for the dual-band LNA 500.

For the operation at the first frequency (e.g., at 5.0 GHz) shown in plot 620 of FIG. 6B, the dual-band LNA 500 provides slight degradation in performance over the dual-band LNA 300. For example, the gain (S21) shows a slight decrease from 31.85 dB to 28.14 dB, the impedance matching (S11) shows a degradation from −37.2 dB to −19.1 dB, and the NF shows a slight degradation from 2.17 dB to 2.20 dB. Although the impedance matching degradation from −37.2 dB to −19.1 dB appears to be significant, any impedance matching number below −10 dB is a very good number and the difference between numbers below −10 dB are not very significant. Therefore, the significant improvements in the numbers for performance parameters of the second frequency (e.g., at 2.4 GHz) are worth the small degradation in the numbers for the first frequency (e.g., at 5.0 GHz).

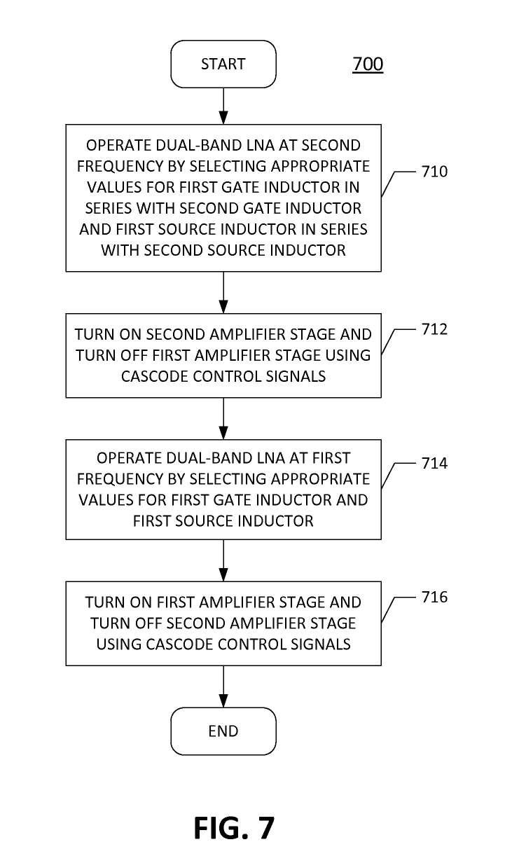

FIG. 7 is an exemplary flow diagram of a process 700 for operating a dual-band LNA in stages according to one exemplary embodiment of the present disclosure. The dual-band LNA is operated at a second frequency, at step 710, by selecting appropriate values for serially-connected first and second gate inductors (e.g., inductor 524 in series with inductor 554 in FIG. 5B) and serially-connected first and second source inductors (e.g., inductor 552 in series with inductor 520 in FIG. 5B). The first amplifier stage (e.g., stage 570 in FIG. 5B) is turned off and the second amplifier stage (e.g., stage 572 in FIG. 5B) is turned on, at step 712, using cascode control signals (i.e., signals V_{cas1} and V_{cas2} in FIG. 5B). In one exemplary embodiment shown in FIG. 5B, the cascode control signal (V_{cas2}) of the second amplifier stage 572 is set to a voltage that is high enough to turn on the cascode transistor 542 which applies current through resistor 560 and charges up capacitor 562. At this operating mode, the first amplifier stage 570 (including transistors 510, 512) is turned off by setting the cascode control signal (V_{cas1}) of the first amplifier stage 570 to the ground voltage. Thus, in this low frequency mode, transistor 540 is the common-source transistor. The gate inductors include two inductors 524 and 554 in series and the source inductors include two inductors 552 and 520 in series. Thus, when operating at the second frequency, gate inductor 554 is added to the existing gate inductor 524 and source inductor 552 is added to the existing source inductor 520.

The dual-band LNA is operated at a first frequency, at step 714, by selecting appropriate values for a first gate inductor (e.g., inductor 524 in FIG. 5B) and a first source inductor (e.g., inductor 520 in FIG. 5B). The first amplifier stage (e.g., stage 570 in FIG. 5B) is turned on and the second amplifier stage (e.g., stage 572 in FIG. 5B) is turned off, at step 716, using cascode control signals (i.e., signals V_{cas1} and V_{cas2} in FIG. 5B). Thus, in one exemplary embodiment shown in FIG. 5B, the cascode control signal (V_{cas1}) of the first amplifier stage 570 is set to a voltage that is high enough to turn on the cascode transistor 512 which applies current through resistor 528 and charges up capacitor 526. At this operating mode, the second amplifier stage 572 (including transistors 540, 542, 550) is turned off by setting the cascode control signal (V_{cas2}) of the second amplifier stage 572 to the ground voltage. Although setting V_{cas2} to the ground voltage turns off the cascode transistor 542 and no current is supplied to transistors 540, 550 and inductor 552, parasitic capacitance from the transistors in the second amplifier stage 572 can cause the capacitance from the second amplifier stage 572 to leak into the first amplifier stage 570. Thus, when the LNA 500 is operating at the high frequency mode with only the first amplifier stage 570, the second amplifier stage 572 is completely turned off by setting V_{cas2} to the ground voltage and also by turning off the source switch transistor 550 (for example, by setting the gate terminal of transistor 550 to the ground voltage). This prevents the parasitic capacitance of the second amplifier stage 572 from leaking into the first branch and interfering with the operation of the first amplifier stage 570.

The dual-band LNA described herein may be implemented on an IC, an analog IC, an RFIC, a mixed-signal IC, an ASIC, a printed circuit board (PCB), an electronic device, etc. The dual-band LNA may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing the dual-band LNA described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the scope of the disclosure. Thus, the disclosure is not intended to be limited to the examples and designs described herein but is to be accorded the widest scope consistent with the principles and novel features disclosed herein.

What is claimed is:

1. An apparatus comprising:
a first amplifier stage configured to receive an input signal through a first gate inductor and a first source inductor; and
a second amplifier stage configured to receive the input signal through the first gate inductor and a second gate inductor, and the first source inductor and a second source inductor.

2. The apparatus of claim 1, the first gate inductor is coupled to a gate terminal of a gain transistor in the first amplifier stage, and the first source inductor is coupled to a source terminal of the gain transistor in the first amplifier stage.

3. The apparatus of claim 2, the gate terminal of the gain transistor in the first amplifier stage is controlled by the first gate inductor.

4. The apparatus of claim 2, the source terminal of the gain transistor in the first amplifier stage is controlled by the first source inductor.

5. The apparatus of claim 1, the second gate inductor is coupled to the first gate inductor and to a gate terminal of a gain transistor in the second amplifier stage, and the second source inductor is coupled to the first source inductor and to a source terminal of the gain transistor in the second amplifier stage.

6. The apparatus of claim 5, the gate terminal of the gain transistor in the second amplifier stage is controlled by the first gate inductor and the second gate inductor arranged in series.

7. The apparatus of claim 5, the source terminal of the gain transistor in the second amplifier stage is controlled by the first source inductor and the second source inductor arranged in series.

8. The apparatus of claim 5, further comprising
a source switch transistor coupled between the source terminal of the gain transistor in the second amplifier stage and the second source inductor.

9. The apparatus of claim 1, further comprising
a load circuit coupled to drain terminals of cascode transistors in the first amplifier stage and the second amplifier stage, the load circuit comprising two inductors and a variable capacitor coupled in parallel.

10. The apparatus of claim 1, the first and second amplifier stages are first and second stages of a low noise amplifier configured to output radio frequency signals.

11. The apparatus of claim 10, further comprising
a plurality of receive circuits configured to receive and downconvert the radio frequency signals from the low noise amplifier to baseband signals.

12. An apparatus comprising:
means for operating a dual-band amplifier at a first frequency by selecting appropriate values for a first gate inductor and a first source inductor; and
means for operating the dual-band amplifier at a second frequency by selecting appropriate values for a second gate inductor in series with the first gate inductor and a second source inductor in series with the first source inductor.

13. The apparatus of claim 12, further comprising:
means for turning on one of first and second amplifier stages of the dual-band amplifier; and
means for turning off another of the first and second amplifier stages.

14. The apparatus of claim 13, said means for turning on and off the first and second amplifier stages comprising
first and second cascode control signals.

15. The apparatus of claim 14, further comprising:
means for setting the first cascode control signal to a ground voltage to turn off the first amplifier stage; and
means for setting the second cascode control signal to a voltage high enough to turn on the second amplifier stage.

16. The apparatus of claim 14, further comprising:
means for setting the first cascode control signal to a voltage high enough to turn on the first amplifier stage; and
means for setting the second cascode control signal to a ground voltage to turn off the second amplifier stage.

17. The apparatus of claim 13, further comprising
means for completely turning off the second amplifier stage when the second amplifier stage is not in use.

18. The apparatus of claim 13, the first gate inductor and the first source inductor comprising
means for providing impedance matching for the first amplifier stage.

19. The apparatus of claim 13, the first and second gate inductors and the first and second source inductors comprising
means for providing impedance matching for the second amplifier stage.

20. The apparatus of claim 12, the dual-band amplifier comprising
a low noise amplifier.
